(19) United States
(12) Patent Application Publication
(10) Pub. No.: US 2014/0327450 A1
(43) Pub. Date: Nov. 6, 2014

(54) DEVICE AND METHOD FOR TESTING THE STATE OF THE CONNECTION OF A LOAD CONNECTED TO A CONNECTION POINT

(71) Applicant: CONTINENTAL AUOMOTIVE GMBH, MUENCHEN (DE)

(72) Inventors: Harald Schmauss, Donaustauf (DE); Sergiu Muresan, Cluj-Napoca (RO); Gunther Wolfarth, Regensburg-Harting (DE); Marco Well, Giessen (DE); Johann Falter, Wenzenbach (DE); Franz Laberer, Regensburg (DE); Christian Theil, Timisoara (RO)

(21) Appl. No.: 14/358,261

(22) PCT Filed: Nov. 14, 2012
(86) PCT No.: PCT/EP2012/072650

§ 371 Date: May 15, 2014

(30) Foreign Application Priority Data
Nov. 15, 2011 (DE) 102011086412.1

(51) Int. Cl. G01R 31/04

(52) U.S. Cl. CPC G01R 31/041
USPC 324/538

(57) ABSTRACT

A device and a method test the connection of a load connected to a connection point. The connection point is formed between a first switching element, which is connected between a high supply voltage potential and the connection point, and a second switching element, which is connected between the connection point and a low supply voltage potential. When the two switching elements are switched off, a potential is built up at the connection point by at least one voltage or current source connected to the connection point. A potential analyzing circuit is provided and checks whether the potential lies in a defined potential range. If this is the case, it is concluded that a line between the connection point and the load has been interrupted.

The invention relates to a device for connecting a load to the high or the low potential of a supply voltage by means of switching elements, and for testing the state of the connection of the load to a connection point between the switching elements, in which device a first switching element is connected between the high supply voltage potential and the connection point, and a second switching element is connected between the connection point and the low supply voltage potential, wherein the device has at least one voltage or current source which can be connected to the connection point, and wherein the device has a potential evaluation circuit which is connected to the connection point.

A device of this kind is known from DE 10 2007 002 953 A1.

A large number of loads have to be switched on and switched off in motor vehicles, wherein power transistors or relays are used owing to the high switching currents which are usually necessary. Corresponding loads can be, for example, the headlights, but also electric motors, for example for window winders, valves, injectors or ignition coils. The corresponding power switches have to be driven in each case, for which purpose either so-called high-side switches, which are connected to the supply voltage by way of one terminal, or low-side switches, which are connected to ground by way of one terminal, are used. Control switches of this kind are usually realized in a relatively large number in ASICs (applicant specific integrated circuit) which, for their part, are driven by control units, such as microprocessors for example.

Circuit arrangements of this kind which are usually realized as ASICs are known, for example, from DE 10 2006 045 308 A1 or DE 199 20 465 C1. DE 199 20 465 C1 also discloses that, instead of a high-side or low-side switch, a push-pull output stage can also be used, said push-pull output stage comprising both a high-side switch and also a low-side switch, which switches can then be selectively connected to the load, so that said load can be selectively connected either to the positive supply voltage potential or ground. This may be of interest when capacitive load components are intended to be discharged in a targeted manner.

Switches of this kind have to be checked in order to determine whether the connection to the switching load is intact or whether there is a line interruption (open load), but also have to be tested for short circuits to the supply voltage potentials and/or overcurrents. In order to check for a line interruption, it is possible in this case—as disclosed in DE 10 2006 045 308 A1—for a specific potential to be applied to, or for a specific current to be impressed at, the connection point of the load to the circuit arrangement, which contains the switching element, in a targeted manner, wherein a check is then made to determine whether the potential which is established is in specific predefined ranges. If the connection is in order, a low potential is usually established since the connected load usually has a low resistance. If, however, there is a line interruption, the potential which is prespecified by the impressed voltage or the impressed current is established, so that said potential can be detected. For the purpose of this test, the high-side or the low-side switch has to be switched off.

DE 199 20 465 C1 discloses, in particular for driving an ignition device, the test with the switching transistor not driven, wherein, however, the increase in voltage at the switching transistor during the line interruption diagnosis is so low that the load is not disconnected during this time.

For the purpose of testing power switching devices which connect a load which is realized in a circuit arrangement which is in the form of an ASIC, DE 10 2004 054 374 B3 discloses a circuit arrangement for providing a diagnosis signal, which circuit arrangement has a test circuit which tests the power switching device and, depending on the testing, generates fault symptoms for characterizing fault types with different priorities, has a filter device which provides a validity signal for the generated fault symptoms in each case depending on a drive signal for driving the power switching devices, wherein the validity signal indicates the validity of the corresponding fault symptom in each case, has a validation device which validates a generated fault symptom depending on the associated validity signal and the drive signal in each case, and, from this, generates a group of states and complementary states which complement said group of states, and has a coding device which codes the states and complementary states depending on priorities of the fault types which are associated with the states and complementary states, wherein the diagnosis signal is formed from the coded states and complementary states.

Proceeding from the above, the problem addressed by the present invention is that of providing line interruption diagnosis in a power switching device which is in the form of a push-pull output stage and can connect a load, in which line interruption diagnosis the diagnosis is performed using simple means.

The problem is solved by a device as claimed in claim 1 and a method as claimed in claim 3. Advantageous developments are specified in the dependent claims.

Accordingly, a device for connecting a load to the high or low potential of a supply voltage with the aid of switching elements, and for testing the state of the connection of the load to a connection point between the switching elements, in which device a first switching element is connected between the high supply voltage potential and the connection point, and a second switching element is connected between the connection point and the low supply voltage potential, has, in line with the invention, a voltage or current source which can be connected to the connection point, and a potential evaluation circuit which is connected to the connection point, wherein the potential evaluation circuit is formed with at least two comparators, wherein the reference input of the first comparator is connected to a voltage source for a low voltage, and the reference input of the second comparator is connected to a voltage source for a voltage for a line interruption.

It is therefore proposed in line with the invention to connect a voltage or a current to the connection point of a load to a switching element, and to evaluate the potential which is established at the connection point, even in the case of a switching element which is in the form of a push-pull output stage.

It is particularly advantageous to use the invention in the case of a load which is formed with a power transistor for supplying current to an ignition coil of a motor vehicle.

In a method for testing the connection of a load which is connected to a connection point, wherein the connection point is formed between a first switching element, which is connected between a high supply voltage potential and the connection point, and a second switching element, which is connected between the connection point and a low supply voltage potential, when the two switching elements are in the switched-off state, in line with the invention, a potential is built up at the connection point by at least one voltage or current source which is connected to the connection point, and a potential evaluation circuit checks whether the potential is in a defined potential range, and, if this is the case, it is concluded that there is a line interruption between the connection point and the load. In line with the invention, the connection of the connection point to a connected load is only checked when the switching elements are both switched off in the case of a switching element which is in the form of a push-pull output stage.

In an advantageous development, the potential at the connection point builds up only after initially the first switching element and then the second switching element have been switched on and switched off again. This is particularly advantageous in the case of a load which is formed by an ignition device in a motor vehicle and which is connected to the supply voltage potential, and as a result is supplied with current, by closing the first switching element, wherein, when the first switching element is disconnected, firstly the ignition device is ignited and secondly the ignition device is switched off in a targeted manner by switching on the second switching element and opening the second switching element again. In this state, the test for a line interruption can advantageously be carried out in a particularly simple manner.

In a further advantageous development of the invention, the potential at the connection point is checked during a prespecified test time period. This test time period can also be made up of several successive individual test time periods.

The test time period is advantageously defined as a function of capacitive components of the load. As a result, it is possible to ensure that the potential at the connection point no longer changes to a significant extent on account of the connected capacitive load.

In a further advantageous development of the invention, a line interruption is checked as part of a prespecified test scheme in which short circuits of the connection point to the high and/or the low supply voltage potential and also further fault symptoms are also tested.

The invention will be described in greater detail below with reference to an exemplary embodiment with the aid of figures, in which

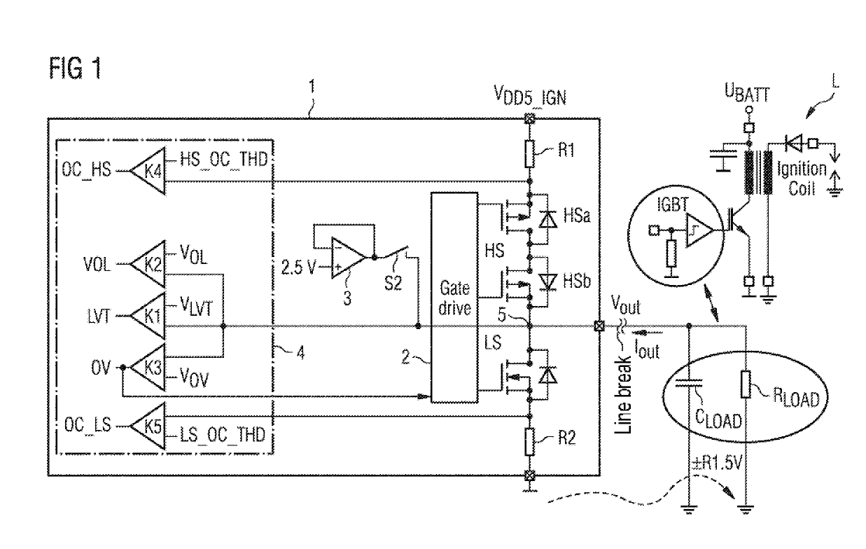

FIG. 1 shows a device according to the invention as a circuit diagram,

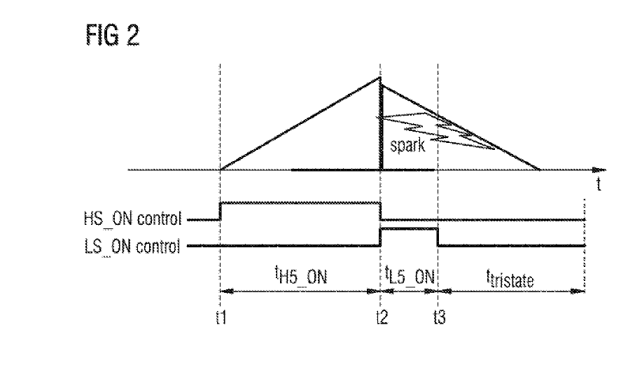

FIG. 2 shows the phases of switching on and switching off the switching element in the case of an ignition device as load,

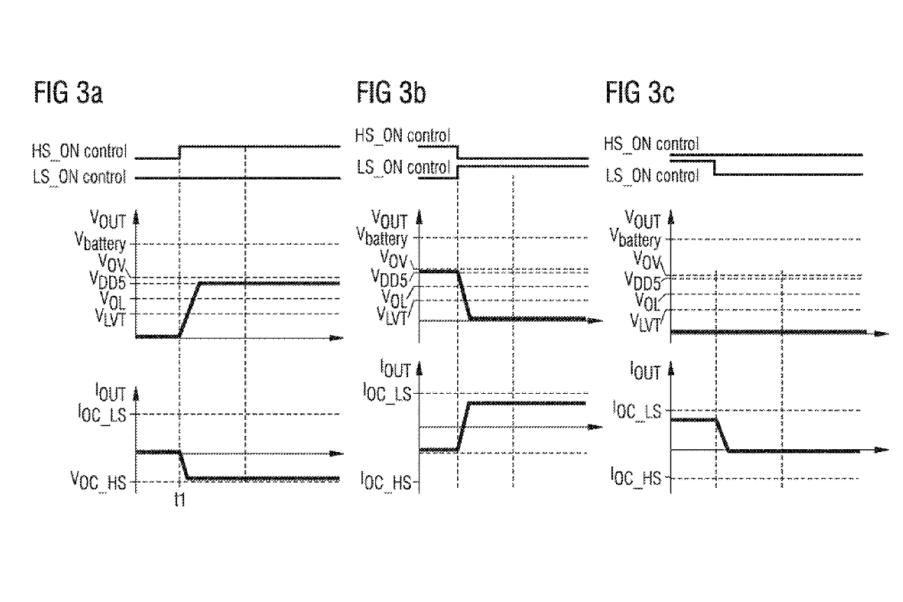

FIG. 3a shows the profile of the voltage and of the current at the connection point when the first switch is switched on and the load is connected,

FIG. 3b shows the profile of the voltage and of the current at the connection point when the second switch is switched on and the load is connected,

FIG. 3c shows the profile of the voltage and of the current at the connection point when both switches are switched off (tristate),

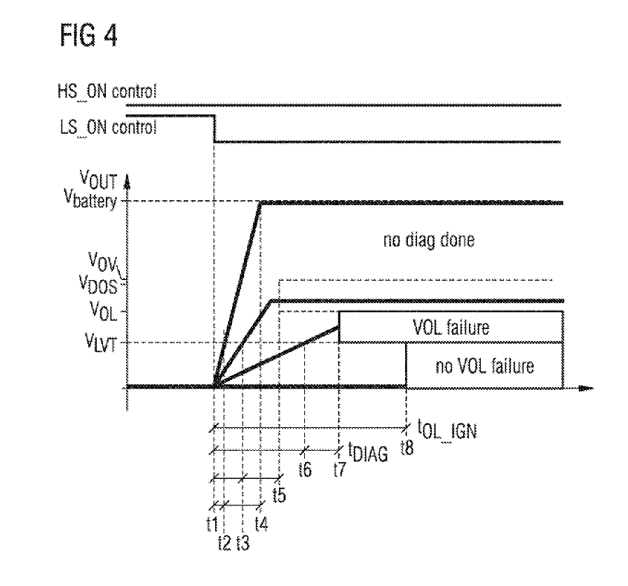

FIG. 4 shows the possible diagnosis results when the switching elements are switched off and the test voltage is connected or the test current is connected,

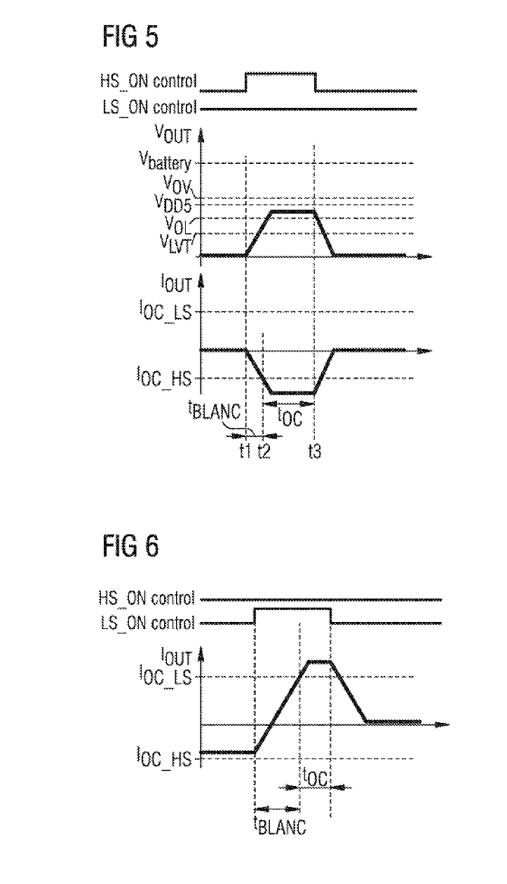

FIG. 5 shows the profile of the voltage and of the current in the event of a short circuit to ground of the connection point (overcurrent), and

FIG. 6 shows the profile of the voltage and of the current at the connection point in the event of a short circuit to the high supply voltage potential at the connection point.

FIG. 1 shows a device 1 according to the invention for testing the connection of a load L which is connected to a connection point 5. In the illustrated exemplary embodiment, the load L is an ignition device for a motor vehicle, the input impedance of said ignition device which is relevant for the device 1 being represented by a load resistor R_{LOAD} and a load capacitor C_{LOAD}. The ignition device comprises an ignition coil which is connected, on the secondary side, to a schematically illustrated spark plug by means of a diode which is operated in the reverse direction, and which is connected, on the primary side, firstly to the battery voltage U_{BATT} and secondly to ground by means of a power transistor IGBT. The power transistor IGBT is driven by means of a buffer amplifier and a series resistor which is connected in front of said buffer amplifier. The series resistor and the buffer amplifier form said input impedance.

The connection point 5, which is connected to a corresponding output pin of the device 1, is connected to the positive potential of the supply voltage V_{DD5}_{_{—}}_{IGN} firstly by means of a semiconductor switch HS, which is formed from two P-channel MOSFETs HSa, HSb which are connected to one another in series by way of their drain connections in the illustrated example, and by means of a first current measurement resistor R1 which is connected in series to the semiconductor switch. The connection point 5 is secondly connected to the ground terminal by means of a second switching element LS, which is formed with an N-channel MOSFET, and a second current measurement resistor R2. The control terminals of the first and the second switching element HS, LS are driven in a known manner by a control circuit 2 (gate drive) in order to connect the load L either to the positive supply voltage terminal V_{DD5}_{_{—}}_{IGN} or to ground.

In line with the invention, a voltage source 3 can be connected to the connection point 5 by means of a switch S2, said voltage source being in the form of a voltage follower and it being possible for a voltage of 2.5 V to be applied to the connection point 5 at a precisely defined current (for example +/−75 μA) in the illustrated example.

A potential evaluation circuit 4 is also connected to the connection point 5, said potential evaluation circuit being formed with three comparators K1, K2, K3, in each case one input of said comparators being connected to the connection point 5. Voltage threshold values for a low voltage V_{LVT} (low voltage threshold), a voltage V_{OL} (open load) and a voltage V_{OV} (overvoltage) are applied to the respective other inputs of the comparators K1, K2, K3. Corresponding signals are output at the outputs of the comparators K1 to K3 when the voltage V_{OUT} at the connection point 5 exceeds the respective voltage threshold values V_{OL}, V_{LVT} and/or V_{OV}.

The potential evaluation circuit 4 also has a fourth comparator K4, one input of said fourth comparator being connected to the connection point of the first switching element HS and the first current measurement resistor R1, and a threshold value for an overcurrent HS_OC_THD being applied to the second input of said fourth comparator. The output of the fourth comparator K4 indicates, at its output, by way of the signal OC HS, whether there is an overcurrent, which is caused by a short circuit in the low-side path for example, flowing in the high-side side path of the output stage, that is to say in the path between the positive supply voltage V_{DD5}_{_{—}}_{IGN} and the connection point 5.

A fifth comparator K5 is provided in the same way, one input of said fifth comparator being connected to the connection point of the second switching element LS and the second current measurement resistor R2, and a voltage threshold value LS_OC_THD being applied to the second input of said fifth comparator, and said fifth comparator providing, at its output, a signal OC_LS which indicates whether there is an overcurrent, which can occur in the event of a short circuit in the high-side path for example, in the low-side path of the power output stage HS, LS.

By means of the exemplary embodiment of a device 1 according to the invention which is illustrated in FIG. 1, it is possible, as will be explained in greater detail with the aid of FIG. 4, by applying a test voltage or a test current to the connection point 5, to identify various states of the connection point 5—in particular a line break in the connection to a connected load L—by means of the potential evaluation circuit 4.

FIG. 2 illustrates how it is possible to operate a load L, which is in the form of an ignition circuit for a motor vehicle, by means of the first switching element HS and the second switching element LS of the device 1. Starting at a time t1, a control signal HS_ON control is applied to the control input of the first switching element HS by the control circuit 2, as a result of which the connected load L is connected to the positive supply voltage potential VDD IGN, and current is applied to the primary coil of the ignition coil by corresponding driving of the power switch IGBT—which is illustrated in FIG. 1—, this being illustrated in FIG. 2 by an increasing current. At time t2, the first switching element HS is disconnected again, as a result of which there is a voltage increase in the secondary branch of the ignition coil of the load L, said voltage increase leading to an ignition spark in the spark plug. In order to remove residual charges from a capacitive component C_{LOAD} of the input impedance of the ignition circuit and therefore to reliably turn off the ignition transistor IGBT, the second switching element LS is switched on by the control circuit 2 by means of the control signal LS ON control and switched off again at a time t3, with the first switching element HS being disconnected. Both switching elements HS, LS are then switched off and the connection point 5 is in a so-called tristate condition; it has a high impedance. In this condition, after an ignition operation of this kind, the test for a line break is advantageously carried out in line with the invention.

With the aid of FIGS. 3a-3c, it should be clear which voltages and currents are established at the connection point 5 in each case with the first switching element active and/or with the second switching element active or if both switching elements are inactive.

According to FIG. 3a, the first switching element HS is switched on at a time t1 by the control circuit 2 by means of the control signal HS_ON control. As a result, the connection point 5 and a load L which is connected to said connection point are connected to the positive supply voltage potential V_{DD5}_{_{—}}_{IGN}, as a result of which—as shown in FIG. 3a—a potential corresponding to the supply potential V_{DD5} is established when the connection of the load L to the connection point 5 is intact. In addition, a current I_{OUT} will flow, the magnitude of said current lying below a threshold value for an overcurrent I_{OC HS}

When, at a time t2, the first switching element HS is switched off again and, at the same time, the second switching element LS is switched on by the control unit 2 by means of a control signal LS_ON_control, the load L will be connected to the ground terminal by means of the second switching element LS when the connection is intact, so that the voltage V_{OUT} at the connection point 5 is established at approximately 0 V when a load capacitor C_{LOAD} which may be present has discharged. For the example of FIG. 3b, it is assumed that the load which is connected to the connection point 5 is at a positive supply potential by way of its other terminal, so that—as illustrated in FIG. 3b—a positive current I_{OUT} will be measured at the connection point 5.

When, finally, at a time t3, the second switching element LS is also switched off and the connection point 5 correspondingly enters a high-impedance state, which is usually called the tristate condition, the current I_{OUT} will be established at 0 A and also the voltage V_{OUT} at the connection point 5 will assume a value of approximately 0 V after a short time which is necessary for discharging capacitors which may be present.

In this tristate condition, the connection of the connection point 5 to a connected load L is now checked. To this end, as has already been explained in relation to FIG. 1, a potential is applied to the connection point 5 by means of a test voltage source 3, said potential lying between two threshold values for a low voltage V_{LVT} and a voltage for a line interruption V_{OL}.

The voltages V_{OUT} at the connection point 5, which voltages are now established on account of various fault states, are illustrated in FIG. 4. Therefore, when, in the tristate condition of the connection point 5, a test voltage of this kind is applied to the connection point 5 by means of the test voltage source 3 at a time t1, and, after a first test time t_{OL}_{_{—}}_{IGN}, the voltage at the connection point 5, which voltage is determined by means of the potential evaluation circuit 4, lies between 0 V and the threshold value for a low voltage V_{LVT} (low voltage threshold) at a time t8, it is concluded that there is no fault, that is to say the connection line is intact (no VOL failure).

However, when the potential at the connection point 5 increases and exceeds the low threshold value V_{LVT}, a second test time t_{DIAG} is started, the voltage at the connection point 5 being checked after said second test time has elapsed. If this voltage lies between the threshold value for a low voltage V_{LVT} and a threshold value for a line interruption V_{OL}, it is concluded that there is a line interruption (VOL failure).

If, however, the voltage is above the threshold value for a line interruption V_{OL} after the second test time t_{DIAG} has elapsed, it is determined that no diagnosis has taken place (no DIAG done). It may be necessary to carry out further tests in order to possibly determine a short circuit since there is an overvoltage.

Further tests of this kind are illustrated, by way of example, in FIGS. 5 and 6, wherein FIG. 5 shows that, in order to determine an overcurrent which is caused, for example, by a short circuit across the second switching element LS, the first switching element HS is switched on and the current is ascertained by means of the fourth comparator K4. If the magnitude of this current is above a threshold I_{OC}_{_{—}}_{HS}, it is concluded that there is a short circuit of the second switching element LS to ground, and the first switching element HS is switched off at a time t3.

In a similar manner, it is possible to conclude, by switching on the second switching element LS and checking the current by means of the fifth comparator K5 and the second current measurement resistor R2, that there is an overcurrent in the high-side path when the ascertained current is above a threshold I_{OC}_{_{—}}_{LS}. In this case too, the second switching element is also switched off after a test time t_{OC} has elapsed, in order to prevent damage to the device on account of excessive heating.

1-8. (canceled)

9. A device for connecting a load to a high potential or a low potential of a supply voltage, by switching elements, and for testing a state of a connection of the load to a connection point between the switching elements, the device comprising:
a first switching element connected between a high supply voltage potential and the connection point;
a second switching element connected between the connection point and a low supply voltage potential;
an energy source selected from the group consisting of a voltage source and a current source, said energy source connected to the connection point; and
a potential evaluation circuit connected to the connection point, said potential evaluation circuit having at least two comparators each having a reference input, said two comparators including a first comparator having said reference input connected to a first voltage source for a low voltage and a second comparator having said reference input connected to a second voltage source for a voltage for a line interruption.

10. The device according to claim 9, the device is configured to connect, as the load, a power transistor for supplying current to an ignition coil of a motor vehicle.

11. A method for testing a connection of a load connected to a connection point, wherein the connection point is formed between a first switching element, connected between a high supply voltage potential and the connection point, and a second switching element, connected between the connection point and a low supply voltage potential, which comprises the steps of:
switching off the first and second switching elements resulting in a switched-off state and a potential being built up at the connection point by an energy source selected from the group consisting of a voltage source and a current source and connected to the connection point; and
checking, via a potential evaluation circuit, if a potential is in a defined potential range between a low voltage and a voltage for a line interruption, and, if the potential is in the defined potential range, it is concluded that there is a line interruption between the connection point and the load.

12. The method according to claim 11, wherein the potential at the connection point builds up after initially the first switching element and then the second switching element have been switched on and switched off again.

13. The method according to claim 11, which further comprises checking that the potential at the connection point during a specified test time period.

14. The method according to claim 13, wherein the specified test time period is defined as a function of capacitive components of the load.

15. The method according to claim 14, wherein the specified test time period is made up of a number of successive individual test time periods.

16. The method according to claim 11, which further comprises checking for the line interruption within a prespecified test scheme in which short circuits of the connection point to the high and/or the low supply voltage potential are also tested.
